(19) United States
(12) Patent Application Publication
(10) Pub. No.: US 2008/0272443 A1
(43) Pub. Date: Nov. 6, 2008

(54) Field effect transistor having field plate electrodes

(75) Inventors: Shinichi Hoshi, Tokyo (JP); Masanori Itoh, Tokyo (JP); Hideyuki Okita, Tokyo (JP); Toshiharu Marui, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/149,325

(22) Filed: Apr. 30, 2008

(30) Foreign Application Priority Data
May 1, 2007 (JP) 2007-120617

(51) Int. Cl. H01L 29/78; H01L 29/778

(52) U.S. Cl. 257/409; 257/194; 257/E29.255; 257/E29.246

(57) ABSTRACT

A field effect transistor includes an active layer formed on a semiconductor substrate, source and drain electrodes formed apart from each other on the active layer, a gate electrode formed between the source and drain electrodes, a first interlayer film formed on the active layer, a first field plate (FP) electrode connected to the gate electrode and provided on the first interlayer film between the gate and drain electrodes, a second interlayer film formed on the first interlayer film, and a second FP electrode connected to the source electrode and provided on the second interlayer film between the first FP and drain electrodes. The field effect transistor is provided which exhibits a comparatively high gain factor at high frequencies.

### BACKGROUND OF THE INVENTION

1. Field of the Invention

The present invention relates to a field effect transistor (FET), and more specifically to an FET having field plate electrodes.

2. Description of the Background Art

A high output power FET which is one of various types of FETs has its drain terminal supplied with a high voltage and therefore, in general, it is necessary to design a power FET having its gate-to-drain leakage current reduced and its gate breakdown voltage increased. In this regard, there is currently known a type of field effect transistor taught by, e.g. U.S. patent application publication No. 2006/0043415 A1 to Okamoto et al., and adapted for forming a field control electrode between its gate and drain electrodes. There is also another type of field effect transistor taught by, e.g. U.S. patent application publication No. 2006/0102929 A1 to Okamoto et al., and provided a field plate (FP) electrode structure in which the overhang portion of a gate electrode extends in the direction toward the drain electrode on a first interlayer dielectric film. As taught by the publications, both of the field effect transistors are designed so as to reduce the electric field concentration between the gate and drain electrodes.

Still another type of field effect transistor is known which has an additional field plate electrode connected to its source electrode, i.e. source field plate (SFP) electrode, formed on a second interlayer dielectric film in order to reduce the electric field concentration between the gate and drain electrodes to a greater extent than the case of the above FP electrode structure, resulting in higher operation voltage and higher output power density than when the conventional FP electrode structure is used, see e.g. R. Therrien et. al., “A 36 mm GaN-on-Si HFET Producing 368 W at 60V with 70% Drain Efficiency” IEDM 2005 Tech. Digest 23.1, and Y. Nanishi et al., “Development of AlGaN/GaN High Power and High Frequency HFETs under NEDO's Japanese National Project” CS MANTECH Conference.

R. Therrien et. al., mentioned above also teaches that the above-stated SFP electrode is formed to reduce a parasitic gate-to-drain capacitance (Cgd), resulting in higher gain at high frequencies.

As described above, the conventional FET having the SFP electrode is capable of reducing the electric field concentration between the gate and drain electrodes and providing higher output power density. Further, as also described in R. Therrien et. al., the presence of the SFP electrode reduces a parasitic gate-to-drain capacitance (Cgd), resulting in higher gain at high frequencies. Likewise, the inventors of the present patent application have shown by the measurements that the presence of the SFP electrode reduces Cgd by about half and causes a 3 dB increase in gain at high frequencies.

However, the SFP electrode in the conventional FET is placed on the second interlayer dielectric film above the gate and FP electrodes. Since the SFP electrode connected to the source electrode is isolated from the FP electrode connected to the gate electrode only by the thickness of the second interlayer dielectric film, the gate-to-source capacitance (Cgs) of the FET increases, unpreferably resulting in a decrease in gain at high frequencies.

### SUMMARY OF THE INVENTION

It is therefore an object of the present invention to provide a field effect transistor having the capacitance between its gate and source electrodes reduced and its gain at high frequencies increased.

A field effect transistor according to the invention comprises: an active layer formed on a semiconductor substrate; source and drain electrodes formed apart from each other on the active layer; a gate electrode formed between the source and drain electrodes; a first interlayer dielectric film formed on the active layer; a first field plate electrode connected to the gate electrode and provided on the first interlayer dielectric film between the gate electrode and the drain electrode; a second interlayer dielectric film formed on the first interlayer dielectric film; and a second field plate electrode connected to the source electrode and provided on the second interlayer dielectric film between the first field plate electrode and the drain electrode.

According to the invention, the second field plate electrode is provided on the second interlayer dielectric film between the first field plate electrode and the drain electrode, thereby reducing the gate-to-source capacitance (Cgs) and increasing gain at high frequencies.

### BRIEF DESCRIPTION OF THE DRAWINGS

The objects and features of the present invention will become more apparent from consideration of the following detailed description taken in conjunction with the accompanying drawings in which:

FIG. 1 is a structural cross-sectional view of an embodiment of a field effect transistor according to the invention;

FIG. 2 is a structural top view of the field effect transistor shown in FIG. 1;

FIGS. 3 through 6 are diagrams showing how the provision of the SFP electrode on the additional interlayer film according to the embodiment provides benefits;

FIGS. 7 through 10 are diagrams showing how the thickness of the SiN layer according to the embodiment provides benefits;

FIGS. 11 through 14 are diagrams showing how the use of the SFP electrode within the FET helps to reduce the electric field concentration;

FIG. 15 is a diagram showing how the value of the cut-off frequency varies with the value of the SFP spacing according to the embodiment;

FIG. 16 is a structural cross-sectional view, like FIG. 1, of an alternative embodiment of a field effect transistor according to the invention;

FIG. 17 is a structural cross-sectional view, like FIG. 1, of another alternative embodiment of a field effect transistor according to the invention;

FIG. 18 is a structural top view, like FIG. 2, of the field effect transistor shown in FIG. 17; and

FIG. 19 is a structural cross-sectional view, like FIG. 1, of a still another alternative embodiment of a field effect transistor according to the invention.

### DESCRIPTION OF THE PREFERRED EMBODIMENTS

Now, with reference to the accompanying drawings, the structure of a field effect transistor according to an embodiment of the present invention will be described. Those drawings are simplified schematic representations intended to generally illustrate the shape, size, and positional relationships of the various structural components to the extent that the present invention can be understood by those skilled in the art. For the purpose of better understanding, the figures are drawn with some dimensions exaggerated. Further, preferred exemplary configurations of the invention will be given below. However, the materials used, numerical conditions and so forth given below are nothing but examples in the scope included in the essence of the invention. Accordingly, the present invention is not limited to the following illustration.

The structure of a field effect transistor (FET) 100 of the embodiment will be described with reference to a hetero structured high electron mobility transistor (HEMT) whose active layer is made of aluminum gallium nitride/gallium nitride (AlGaN/GaN), hereinafter referred to as GaN-HEMT. Note that the invention is not limited to such a specific configuration, but may be applied to a gallium arsenide (GaAs) FET whose active layer is made of GaAs. The active layer may be made of another material. Further, the invention may be applied to an FET of the metal insulator semiconductor (MIS) type and that of metal oxide semiconductor (MOS) type.

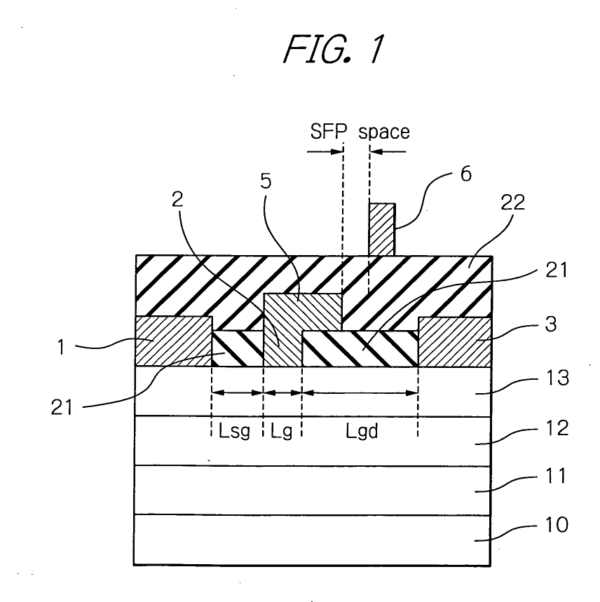

FIG. 1 is a structural cross-sectional view of the FET 100 according to the embodiment. In FIG. 1, the FET 100 according to the embodiment has a source electrode 1, a gate electrode 2, a drain electrode 3, a field plate (FP) electrode 5, another FP electrode 6 serving as a source field plate (SFP) electrode, a semiconductor substrate 10, a buffer layer 11, a GaN channel 12, an AlGaN electron supply layer 13, an interlayer film 21 serving as an interlayer dielectric film and another interlayer film 22 serving as another interlayer dielectric film. In the figures, some of the cross sections are indicated without hatchings merely for the purpose of simplicity.

The substrate 10 is made of crystalline semi-insulating silicon carbide (SiC). Formed on one of the principal surfaces of the substrate 10 is the buffer layer 11. The buffer layer 11 is consisted of aluminum nitride (AlN), for example, and formed to a suitable for design, optional and preferable thickness by MOCVD (metal organic chemical vapor deposition) method, for instance. The GaN channel 12 is nominally undoped GaN material, which is grown, for example, by MOCVD on the buffer layer 11 to an intended, optional, and preferable thickness. The AlGaN electron supply layer 13 is consisted of undoped AlGaN material, which is deposited on the GaN channel 12 by a fabrication method such as MOCVD. The GaN channel 12 and AlGaN layer 13 form an active layer.

On the hetero-interface between the GaN channel 12 and AlGaN electron supply layer 13, the piezo-electric effect caused by a lattice mismatch induces and stores electrons in the GaN channel 12 near the hetero-interface. The induced and stored electrons form a two-dimensional electron layer. Further, formed on the electron supply layer 13 are the source electrode 1 and drain electrode 3 spaced apart from each other and formed in ohmic contact with the layer 13. Moreover, formed between the source electrode 1 and drain electrode 3 is the gate electrode 2 spaced apart from the electrodes 1 and 3 and formed in Schottky contact with the layer 13. Additionally, integrally formed with the gate electrode 2 is the FP electrode 5 extending towards the drain electrode 3 to form an overhang. The electron supply layer 13 has its surface covered with the interlayer film 21 formed of silicon nitride (SiN), for example, which is disposed just under the FP electrode 5.

Formed on the interlayer film 21 is the interlayer film 22 consisted of SiN, for instance. The interlayer film 22 covers the source electrode 1, the gate electrode 2, the FP electrode 5 and the drain electrode 3. Further, formed between the FP electrode 5 and drain electrode 3 on the film 22 is the FP electrode 6 connected to the source electrode 1 and disposed so as not to overlap, i.e. coat, the FP electrode 5 and drain electrode 3.

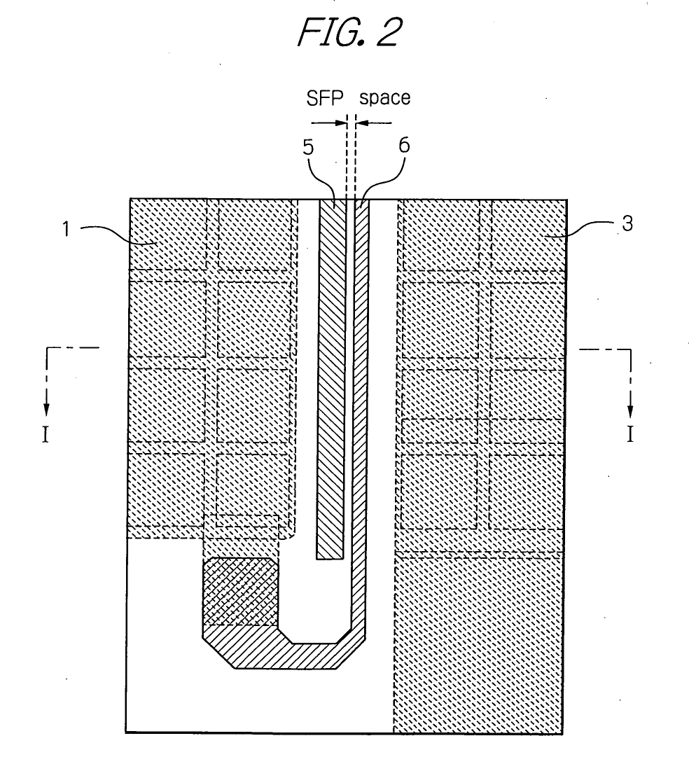

FIG. 2 is a structural top view of the FET 100. As shown in FIG. 2, the FP electrode 6 serving as an SFP electrode (SFP 6) travels around the tip end of the gate electrode 2 and FP electrode 5 and is connected through an interconnection layer to the source electrode 1. Note that FIG. 1, described above, is a cross sectional view of the transistor 100 taken along a chain-dotted line I-I shown in FIG. 2.

In accordance with the embodiment described above, the SFP 6 is placed apart from the gate electrode 2 and FP electrode 5 and between the gate and drain electrodes to reduce the electric field concentration between the gate and drain electrodes, and reduce the gate-to-source capacitance (Cgs) due to the presence of the SFP 6. Dimensions of the respective parts of the FET according to the embodiment will now be given in detail below. Note that in what follows, “the distance between electrodes” means the distance parallel to the surface of the substrate 10, i.e. horizontal to the surface of the substrate, in other words, the distance as measured in the top view.

Referring again to FIG. 1, the SFP 6 is arranged so that a distance between the ends of the SFP 6 and FP electrode 5, i.e. SFP spacing, is at least greater than 0 micrometer (μm). In short, it is important for the FP electrode 6 not to overlap, or coat, the FP electrode 5. Further, the SFP spacing is desirably not greater than 2.0 μm. The reason why the value of not greater than 2.0 μm is desirable is that the FET without the FP electrodes 5 and 6 has a cut-off frequency of 12 gigahertz (GHz) and therefore the FET with those FP electrodes cannot have a cut-off frequency of not less than 12 GHz even if the SFP spacing is elongated.

The SFP spacing should comply with the constraint on the gate-to-drain electrode distance (Lgd). Specifically, a distance between the end of the FP electrode 6 on the side of the drain electrode 3 and the end of the electrode 3 is desirably not less than 2.0 μm. Because the SFP 6 is connected to the source electrode 1, a source-to-drain electric field could possibly break insulation when the SFP 6 is placed too close to the drain electrode 3.

As described above, the SFP 6 is arranged so as not to overlap vertically with the FP electrode 5 connected to an electrode to which the SFP 6 is not connected. In the following, the basic principle to determine the position of the SFP 6 in the vertical direction will be set forth.

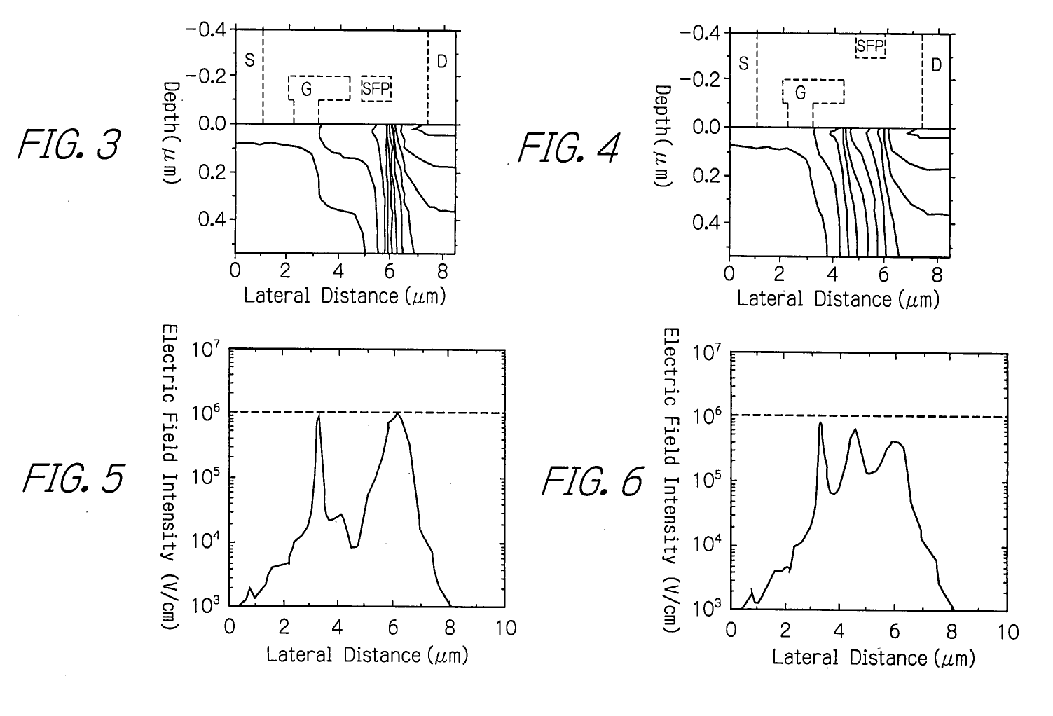

First, how the provision of the SFP 6 on the additional interlayer film provides benefits will be demonstrated. As described above, the SFP 6 has been formed on the interlayer film 22 which overlies the FP electrode 5. Thus, the interlayer film 22 prevents short-circuiting between the FP electrode 5 (connected to the gate) and the SFP 6 (connected to the source) having a different potential than the FP electrode 5. In addition, the presence of the SFP 6 on the interlayer film 22 serves to reduce the electric field concentration to a greater extent than when the SFP 6 is located on the same level as the FP electrode 5. How the use of the SFP 6 and FP electrode 5 positioned at different levels provides benefits will be discussed with reference to FIG. 3.

FIGS. 3 to 6 are diagrams showing how the provision of the SFP electrode on the interlayer film 22 according to the embodiment provides benefits. More specifically, FIG. 3 displays the calculation results for a potential distribution when the FP electrode 6 (SPF) is located at the same level as the FP electrode 5, while FIG. 4 displays the results when the SPF 6 is located at a different level than the FP electrode 5. FIG. 5 displays the electric field intensity distribution of a region at a depth of 25 nanometers (nm) below the surface when the SFP 6 is located at the same level as the FP electrode 5, while FIG. 6 displays the distribution of that region when the SFP 6 is located at a different level than the FP electrode 5.

Note that in FIGS. 3 to 6, bias conditions are Vds=100 volts (V), Vg=0 V, and the surface (depth=0) is the top surface of the AlGaN electron supply layer 13. Further, in FIGS. 3 and 4, the potential distribution of the active layer (depth >0 in the figures) is shown through equipotential lines (drawn at steps of 10 V) and more closely spaced equipotential lines represent an area where high electric fields exist. Moreover, in FIGS. 5 and 6, an electric field intensity of 10⁶ V/cm is denoted by a dot line.

As shown in FIGS. 3 to 6, an electric field intensity and the electric field concentration between the gate and drain electrodes can be reduced to a greater extent when the SFP 6 is located at the different level than the FP electrode 5, i.e. the SFP 6 is located on the interlayer film 22 than when the SFP 6 is located at the same level as the FP electrode 5.

Next, how the thickness of the interlayer film 22 serves to reduce the electric field concentration will be described. From the above discussion, it will be found that the thickness of the interlayer film 22 is also a parameter which can be adjusted to reduce the electric field concentration. In the numerical simulation, the thickness of the interlayer film 22 is effective in the range of 100 to 400 nm in terms of film of silicon nitride (SiN). When the interlayer film 22 is too thin, the benefits achieved by forming the SFP electrode on the film 22 disappear and a decrease in the electric field concentration is not achieved, whereas when the interlayer film 22 is too thick, the benefits achieved by forming the SFP 6 to reduce the electric field concentration become smaller. Note that the thickness of not less than 100 nm in terms of nm of film of SiN is determined based on actual measurements. The thickness of not greater than 400 nm in terms of SiN is determined from numerical simulation.

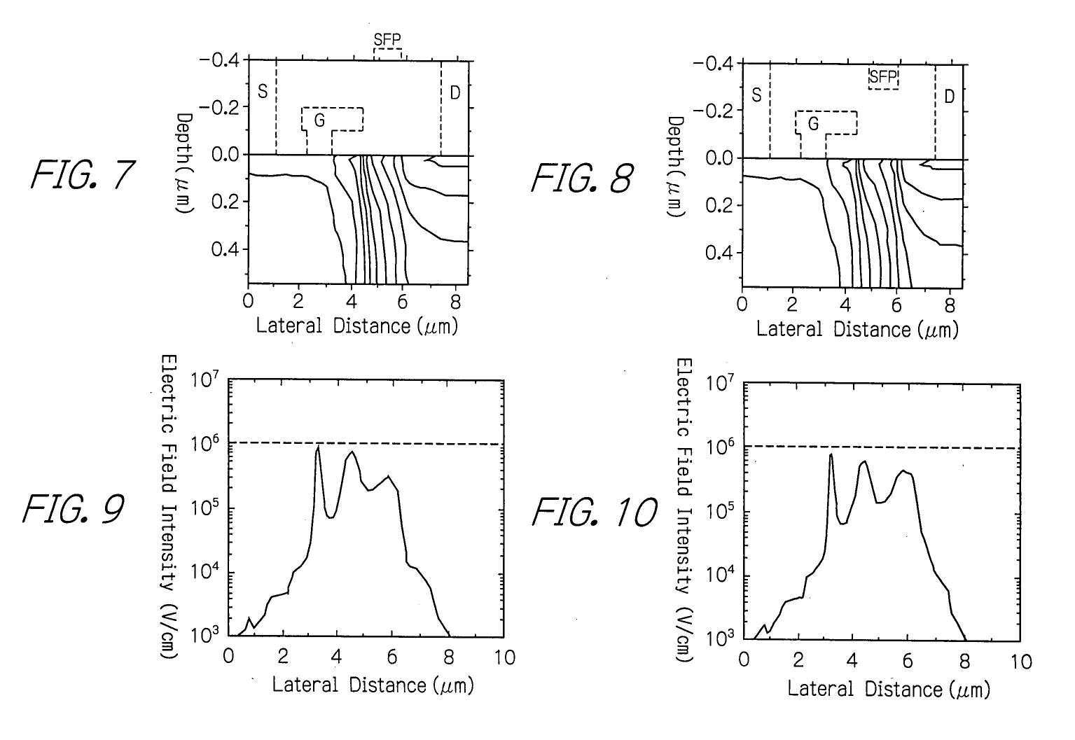

How the above defined thickness of the interlayer film 22 serves to reduce the electric field concentration, referred to as SiN film thickness effect, will be described with reference to FIGS. 4 to 7. FIGS. 7 to 10 are diagrams showing the SiN film thickness effect. FIG. 7 displays the calculation results for a potential distribution when the interlayer film 22 has a thickness of 400 nm in terms of film of SiN. FIG. 8 displays the calculation results for a potential distribution when the interlayer film 22 has a thickness of 200 nm in terms of SiN. FIG. 9 displays the electric field intensity distribution of a region at a depth of 25 nm below the surface when the interlayer film 22 has a thickness of 400 nm in terms of SiN. FIG. 10 displays the electric field intensity distribution of a region at a depth of 25 nm below the surface when the interlayer film 22 has a thickness of 200 nm in terms of SiN.

Note that in FIGS. 7 to 10, bias conditions are Vds=100 V, Vg=0 V, and the surface (depth=0) is the top surface of the AlGaN electron supply layer 13. Further, in FIGS. 7 and 8, the potential distribution of the active layer (depth >0 in the figures) is shown through equipotential lines (drawn at steps of 10 V) and more closely spaced equipotential lines represent an area where high electric fields exist. Moreover, in FIGS. 9 and 10, an electric field intensity of 10⁶ V/cm is denoted by a dot line.

As shown in FIGS. 7 to 10, the electric field concentration may be reduced even when the thickness of the interlayer film 22 is 400 nm in terms of film of SiN. However, the degree of the concentration reduction is smaller than when the thickness of the film 22 is 200 nm in terms of film of SiN. In this way, instead of forming the interlayer film 22 to have a thickness of 400 nm in terms of film of SiN, forming the film 22 to have a thickness of 200 nm in terms of film of SiN helps to reduce the maximum electric field intensity and the electric field concentration between the gate and drain electrodes.

For exemplary purposes, dimensions which are suitable for the FET in the embodiment are suggested from the above study as follows:

source-to-gate electrode distance (Lsg): 1.5 μm

gate electrode length (Lg): 0.7 μm

length of FP electrode 5 (overhang portion): 0.9 μm

SFP spacing length: 1.0 μm

length of FP electrode 6: 1.0 μm

gate-to-drain electrode distance (Lgd): 4.9 μm

distance between FP electrode 6 and drain electrode: 2.0 μm

thickness of interlayer film 21: 100 nm (in terms of film of SiN)

thickness of interlayer film 22: 200 nm (in terms of film of SiN)

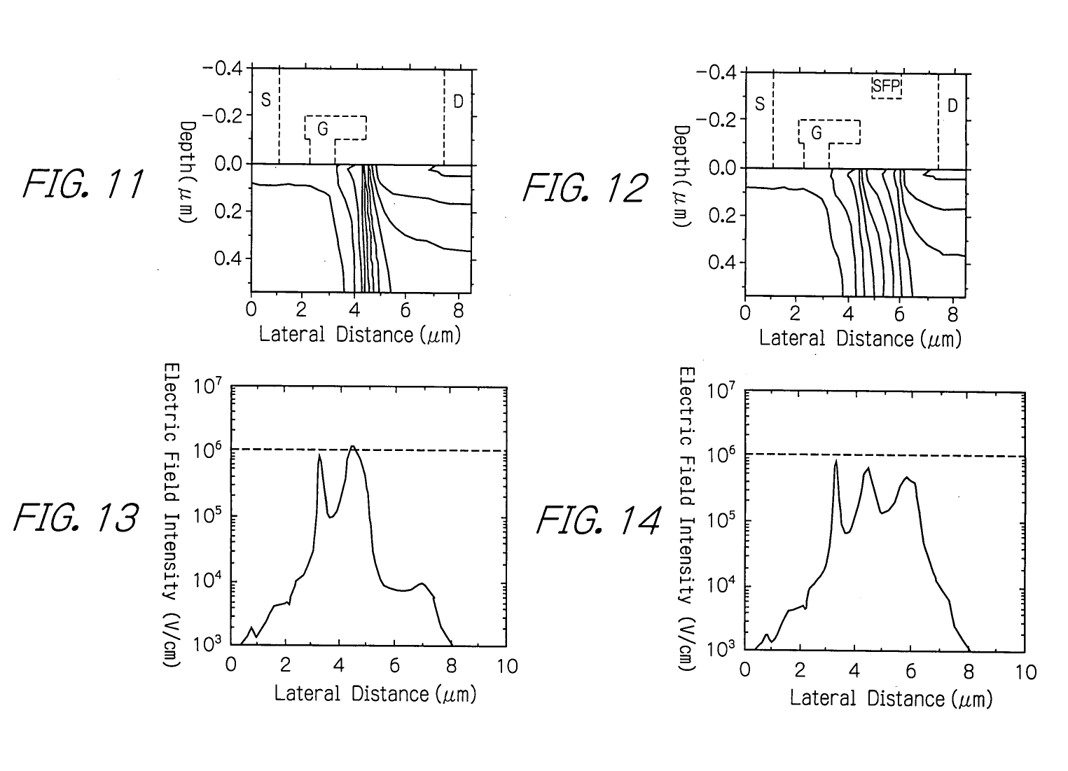

How the use of SFP 6 within the FET having the dimensions as described above helps to reduce the electric field concentration, i.e. SFP effect, will be described with reference to FIGS. 11 to 14. FIGS. 11 to 14 are diagrams showing the SFP effect according to the embodiment. More specifically, FIG. 11 displays the calculation results for a potential distribution when the FP electrode 6 (SPF) is not provided, while FIG. 12 displays the results when the SFP 6 is provided. FIG. 13 displays the electric field intensity distribution of a region at a depth of 25 nm below the surface when the SFP 6 is not provided, while FIG. 14 displays the distribution of that region when the SFP 6 is provided.

Note that in FIGS. 11 to 14, bias conditions are Vds=100 V, Vg=0 V, and the surface (depth=0) is the top surface of the AlGaN electron supply layer 13. Further, in FIGS. 11 and 12, the potential distribution of the active layer (depth >0 in the figures) is shown through equipotential lines (drawn at steps of 10 V) and more closely spaced equipotential lines represent an area where high electric fields exist. Moreover, in FIGS. 13 and 14, an electric field intensity of 10⁶ V/cm is denoted by a dot line.

As shown in FIGS. 11 to 14, the maximum electric field intensity and the electric field concentration between the gate and drain electrodes can be reduced to a greater extent when the SFP 6 is provided than when the SFP is not provided.

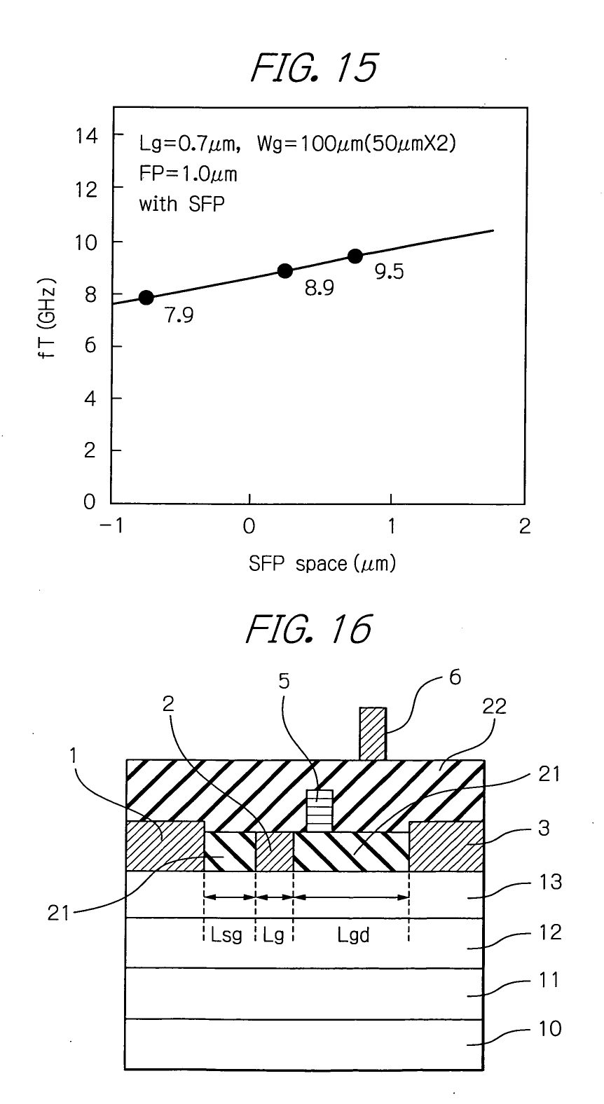

Next, how the value of the cut-off frequency varies with the value of the SFP spacing of the FET having the above-described configuration will be described with reference to FIG. 15. FIG. 15 shows how the value of the cut-off frequency varies with the value of the SFP spacing according to the embodiment. Note that the negative part of the abscissa defines a situation where the FP electrodes 5 and 6 overlap with each other and the positive part of the abscissa does a situation where the FP electrodes 5 and 6 do not overlap with each other.

As shown in FIG. 15, the cut-off frequency (fT) of the GaN-FET having the geometric dimensions according to the embodiment was measured and the resulting cut-off frequency fT was 9.5 GHz. The measurement conditions were such that the GaN-FET was measured in common-source configuration and the power supply voltage (Vdd) was 10 V. Further, the gate width (Wg) of the GaN-FET was 100 μm (finger length was 50 μm).

As can be seen from FIG. 15, the cut-off frequency fT of the conventional structure is 7.9 GHz and an increase in the SFP spacing causes the cut-off frequency of the FET to increase. In this way, the placement of the FP electrode 6 so as not to overlap the FP electrode 5 allows for an increase in the cut-off frequency.

It is important to note that we found experimentally that when the FP electrode 6 is connected to the gate electrode 2, the parasitic capacitance (Cgd) is not reduced and the FET does not have the advantage of a better power gain at a relatively high frequency of operation.

As described above, in the embodiment, the FP electrode 6 is arranged not to overlap the gate electrode 2 and the FP electrode 5, and the FP electrodes 5 and 6 are connected to the gate and the source, respectively. Further, the FP electrode 6 is at a different level from the gate electrode 2 and the FP electrode 5 on which the interlayer film 22 is laid. In this case, the thickness of the interlayer film 22 is preferably 100 to 400 nm. When a distance between the FP electrodes 5 and 6 is at least 100 nm, the electric field concentration between the gate and drain regions can be reduced and the gate-to-source capacitance (Cgs) due to the presence of the FP electrode 6 can be reduced, allowing the FET 100 to exhibit a comparatively high gain factor at high frequencies. This allows an FET to have far better high-frequency characteristics than the conventional high power device.

While the foregoing embodiment has been shown and described as having the FP electrode 5 formed integrally with the gate electrode 2, an alternative embodiment having the FP electrode 5 connected to the gate electrode 2 by way of an interconnection placed external to the FET will be described. Note that elements like those in the foregoing embodiment are denoted in the following by the same reference numerals.

FIG. 16 is a structural cross-sectional view of a field effect transistor 200 in accordance with the alternative embodiment. As shown in FIG. 16, the FP electrode 5 is formed separately from the gate electrode 2 and connected via a wiring layer to the electrode 2. The FP electrode 5 is provided on an interlayer film 21 between the gate electrode 2 and the drain electrode 3. Further, as with the case with the foregoing embodiment, the FP electrode 6 is located between the FP electrode 5 and the drain electrode 3. The remaining configuration and the geometric dimensions may be the same as the embodiment of the FET 100.

Also in the configuration, the cut-off frequency fT achieved by the above GaN-FET 100 can be obtained and the advantages similar to those exhibited by the FET 100 can be achieved. That is, when the electrodes 2 and 5 are at the same electrical potential, the same advantages as the embodiment shown in FIG. 1 can be achieved.

While the embodiment having the FP electrode 5 formed in integral with the gate electrode 2 has been described, a still another embodiment having the FP electrode 5 connected to the gate electrode 2 while covering the electrode 2 will be described.

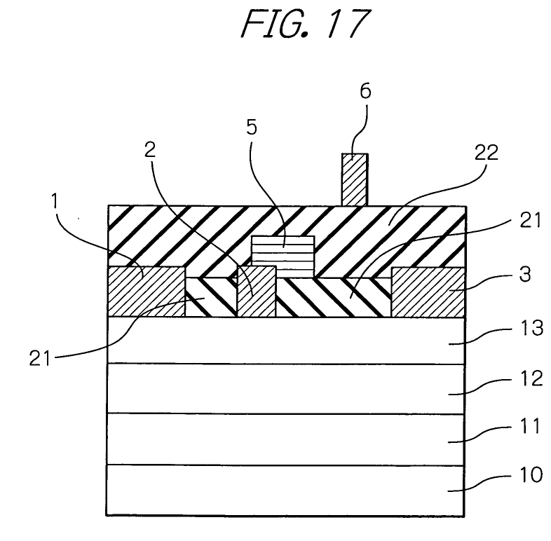

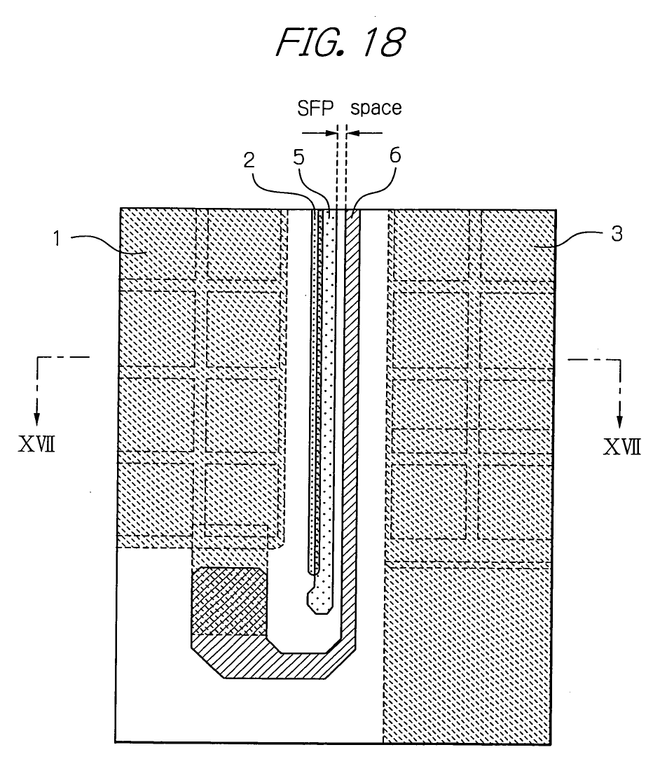

FIG. 17 is a structural cross-sectional view of a field effect transistor 300 in accordance with an embodiment different from the embodiments shown in FIGS. 1 and 16. FIG. 18 is a structural top view of the FET 300. FIG. 17 shows a transversal cross section of the FET 300 taken along a chain-dotted line XVII-XVII of FIG. 18.

Referring now to FIGS. 17 and 18, the FP electrode 5 of the embodiment is made of a metal different from that of the gate electrode 2. For example, the gate electrodes 2 and 5 are made of Ni/Au and Ti/Pt/Au, respectively. The FP electrode 5 is connected to the gate electrode 2 while covering the electrode 2. Further, as shown in FIG. 18, the FP electrode 5 is provided on the interlayer film 21 between the gate electrode 2 and the drain electrode 3. Moreover, as with the case with the embodiment of the FET 100, the FP electrode 6 is located between the electrodes 5 and 3. The remaining configuration and the geometric dimensions may be the same as the embodiment of the FET 100.

As commonly observed for standard GaN-HEMT structures, the gate electrode 2 (Schottky gate electrode) is made of Ni/Au. The Ni/Au metal is poor in adhesion to the interlayer film 21 and therefore it is not preferred that the FET 100 has the gate electrode 2 and the FP electrode 5 formed in integral with each other. Instead, it is preferred that as understood from the present embodiment, the FP electrode 5 is made of Ti/Pt/Au for the purpose of improvement of adhesion to the interlayer film 21.

Also in that configuration, the cut-off frequency achieved by the above GaN-FET can be obtained and the same advantages as the embodiment shown in FIG. 1 can be achieved.

While the foregoing embodiments have been shown and described as having only the FP electrode 6 connected to the source electrode 1 and serving as a field plate, an embodiment will be described which has, in addition to the FP electrode 6, FP electrodes 8 and 9 connected to the source and formed on the respective interlayer dielectric films for the purpose of reducing the electric field concentration to a greater extent and allowing for operation at higher voltages.

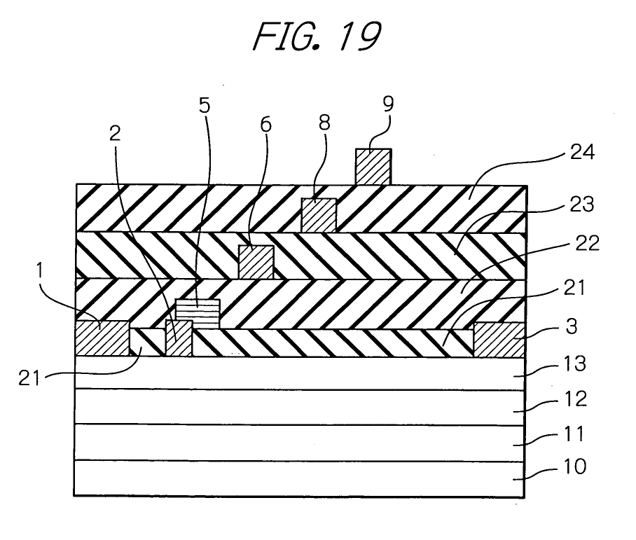

FIG. 19 is a structural cross-sectional view of an FET 400 in accordance with the embodiment having such a configuration stated above. As shown in FIG. 19, the FET 400 has, in addition to the elements already illustrated and described in connection with the previous embodiments, an interlayer dielectric film 23 serving as another interlayer dielectric film, the FP electrode 8 on the film 23, an interlayer dielectric film 24 serving as still another interlayer dielectric film and the FP electrode 9 on the film 24.

The interlayer film 23 is consisted of, for example, SiN and is formed on the top of the interlayer film 22. The interlayer film 23 overlies the FP electrode 6. Further, formed on the interlayer film 23 between the FP electrode 6 and the drain electrode 3 is the FP electrode 8, which is connected to the source electrode 1 and located so as not to overlap or overlie the FP electrode 6 and the drain electrode 3.

Further, formed on the top of the interlayer film 23 is the interlayer film 24 consisted of, for example, SiN, which in turn overlies the FP electrode 8. Further, formed on the interlayer film 24 between the FP electrode 8 and the drain electrode 3 is the FP electrode 9, which is connected to the source electrode 1 and located so as not to overlap the FP electrode 8 and the drain electrode 3.

Moreover, the FP electrode 8 is arranged so that a distance between the ends of the FP electrodes 8 and 6, i.e. SFP spacing, is at least greater than 0 μm. In short, it is important for the FP electrode 8 not to overlap the FP electrode 6. Further, the SFP spacing is desirably not greater than 2.0 μm. Likewise, the FP electrode 9 is also arranged so that a distance between the ends of the FP electrodes 9 and 8, or SFP spacing, is at least greater than 0 μm. Further, the SFP spacing is desirably not greater than 2.0 μm.

In order for the FET 400 of the embodiment to exhibit a comparatively high gain factor at high frequencies as is the case with respect to the foregoing embodiments, the FP electrode 5 connected to the gate and the FP electrode 6 connected to the source should comply with a certain arrangement rule for the embodiment of the FET 100. The reason for this is that an increase in parasitic gate-to-source capacitance (Cgs) arises only due to the space between the two FP electrodes 5 and 6. Note that the number of the FP electrodes depends on the gate-to-drain electrode distance (Lgd) and further the thickness of the interlayer films. In addition, for proper operation of the FET 400, it is a condition to prevent the FP electrodes from overlapping one another in order to reduce the electric field concentration.

As described above, the FP electrodes 5, 6, 8 and 9 do not overlap one another and the number of the SFP electrodes located on the side of the drain increases in proportion to an increase in number of the interlayer films, thereby reducing the electric field concentration. In this case, the extent to which the electric field concentration is reduced depends on the gate-to-drain electrode distance (Lgd) and the thickness of the interlayer films. Therefor, taking the first-described embodiment into account, the suitable conditions for forming the individual FP electrodes so as not to overlap one another in order to reduce the electric field concentration will be concluded, for example, such that a distance between the individual FP electrodes satisfies a relationship of 0<SFP. spacing ≦2.0 μm, the total thickness of the interlayer films is not greater than 400 nm, and a distance between the edge of the SFP electrode closest to the drain electrode 3 and the electrode 3 is not less than 2.0 μm.

Thus, it can be desirable that the total thickness of the interlayer films 22, 23 and 24 disposed on the FET 400 be 100 to 400 nm in terms of film of silicon nitride (SiN).

As described so far, in addition to the advantages of the embodiment of the FET 100, the embodiment of the FET 400 provides the following advantages. That is, because the FET 400 includes the FP electrodes 8 and 9, both of which are located so as not to overlap each other, the FET 400 serves to reduce the electric field concentration to a greater extent and is intended to allow for operation at higher voltages.

The entire disclosure of Japanese patent application No. 2007-120617 filed on May 1, 2007, including the specification, claims, accompanying drawings and abstract of the disclosure, is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. A field effect transistor comprising:
an active layer formed on a semiconductor substrate;
a source electrode and a drain electrode formed apart from each other on said active layer;
a gate electrode formed between said source electrode and said drain electrode;
a first interlayer dielectric film formed on said active layer;
a first field plate electrode connected to said gate electrode and provided on said first interlayer dielectric film between said gate electrode and said drain electrode;
a second interlayer dielectric film formed on said first interlayer dielectric film; and
a second field plate electrode connected to said source electrode and provided on said second interlayer dielectric film between said first field plate electrode and said drain electrode.

2. The field effect transistor in accordance with claim 1, wherein said second field plate electrode is provided so as not to overlap said first field plate electrode and said drain electrode.

3. The field effect transistor in accordance with claim 1, said second field plate electrode is provided so that a distance between an edge of said second field plate electrode and an edge of said first field plate electrode is greater than 0 and not greater than 2.0 μm.

4. The field effect transistor in accordance with claim 3, wherein said second field plate electrode is provided so that a distance between the edge of said second field plate electrode and an edge of said drain electrode is not less than 2.0 μm.

5. The field effect transistor in accordance with claim 1, wherein a thickness of said second interlayer dielectric film is not less than 100 nm and not greater than 400 nm in terms of film of silicon nitride.

6. The field effect transistor in accordance with claim 1, further comprising:
a third interlayer dielectric film formed on said second interlayer dielectric film; and
a third field plate electrode connected to said source electrode and provided on said third interlayer dielectric film between said second field plate electrode and said drain electrode.

7. The field effect transistor in accordance with claim 6, wherein said third field plate electrode is provided so that a distance between an edge of said third field plate electrode and an edge of said second field plate electrode is greater than 0 and not less than 2.0 μm.

8. The field effect transistor in accordance with claim 6, wherein a total thickness of said second and third interlayer dielectric films is not less than 100 nm and not greater than 400 nm in terms of film of silicon nitride.

9. The field effect transistor in accordance with claim 6, further comprising:
a fourth interlayer dielectric film formed on said third interlayer dielectric film; and
a fourth field plate electrode connected to said source electrode and provided on said third interlayer dielectric film between said third field plate electrode and said drain electrode.

10. The field effect transistor in accordance with claim 9, wherein said fourth field plate electrode is provided so that a distance between an edge of said fourth field plate electrode and the edge of said third field plate electrode is greater than 0 and not less than 2.0 μm.

11. The field effect transistor in accordance with claim 9, wherein a total thickness of said second interlayer dielectric film, said third interlayer dielectric film and said fourth interlayer dielectric film is not less than 100 nm and not greater than 400 nm in terms of film of silicon nitride.

12. The field effect transistor in accordance with claim 1, wherein said field effect transistor is a hetero structured High Electron Mobility Transistor (HEMT) whose active layer is made of Aluminum Gallium Nitride/Gallium Nitride (AlGaN/GaN).

13. The field effect transistor in accordance with claim 1, wherein said field effect transistor is an GaAs field effect transistor whose active layer is made of GaAs.

14. The field effect transistor in accordance with claim 1, wherein said field effect transistor is of a metal insulator semiconductor (MIS) type.

15. The field effect transistor in accordance with claim 1, wherein said field effect transistor is of a metal oxide semiconductor (MOS) type.
